(19) United States
(12) Patent Application Publication
(10) Pub. No.: US 2007/0228499 A1
(43) Pub. Date: Oct. 4, 2007

(54) MEMS device package with thermally compliant insert

(75) Inventors: John Dangtran, San Jose, CA (US); Roger Horton, Sunnyvale, CA (US)

Correspondence Address: THELEN REID BROWN RAYSMAN & STEINER LLP, P. O. BOX 640640, SAN JOSE, CA, 95164-0640, US

(73) Assignee: S3C, Inc., Sunnyvale, CA (US)

(21) Appl. No.: 11/544,089

(22) Filed: Oct. 6, 2006

Related U.S. Application Data
(60) Provisional application No. 60/787,909, filed on Mar. 31, 2006.

(51) Int. Cl. H01L 29/84

(52) U.S. Cl. 257/416

(57) ABSTRACT

A low cost micro-electronic package for MEMS applications includes a package substrate, a MEMS device and a buffer insert which is placed between the MEMS device and the package substrate. The buffer insert has a coefficient of thermal expansion (CTE) which is compatible with the material of the MEMS device and is sufficiently rigid to isolate the MEMS device from thermal, mechanical and other physical stresses applied to the package substrate. In an embodiment, the package is formed as an integrated device which includes both the MEMS device and a signal conditioning integrated circuit, potentially found in the same die. The substrate insert may be made of a material having a CTE value compatible with silicon (Si), such as Kovar, Invar, or an appropriate ceramic material or the like.

### STATEMENT OF RELATED APPLICATION

The present application claims the benefit of priority based on U.S. Provisional Patent Application Ser. No. 60/787,909, filed on Mar. 31, 2006, in the name of inventors John Dangtran and Roger Horton, entitled “MEMS DEVICE PACKAGE WITH RIGID INSERT”, all commonly owned herewith.

### TECHNICAL FIELD

The present invention relates to the field of sensing devices. More particularly, the present invention relates to a MEMS device package having a buffer insert and methods for manufacturing thereof.

### BACKGROUND

Micro Electrical-Mechanical System (MEMS) sensors are very small and effective devices which are placed in small packages to produce small transducers. With the development of very small MEMS sensors, it is possible to develop a complete, fully calibrated, high level pressure transducer in a semiconductor package, such as small outline integrated circuit (SOIC), quad flat pack no-lead (QFN), surface mount technology (SMT) and other semiconductor packaging types. However, the MEMS sensors in such small packages are subject to both mechanical and thermal stresses which can severely affect accuracy in the reading and output of the MEMS sensors.

Molded thermo-set and thermo-plastic packaging can transmit mechanical stresses to the MEMS die via the die paddle, which is generally the packaging substrate, lead frame structure or other wired substrate. However, the MEMS die requires a stable substrate to perform properly and provide accurate results. As shown in FIG. 6, a MEMS device 204 is shown attached directly to the lead frame structure 208 as well as the substrate of the package 202. Temperature changes cause expansion or contraction to occur in the lead frames 208 as well the package material. This expansion/contraction causes physical stresses to occur in the materials. Considering that the MEMS sensor is attached directly to this material, the physical stresses are transferred to the MEMS sensor which can, in turn, adversely affect the MEMS device as well as the operation of the entire package in general. Micro-electronic packages are generally very small and so the physical stresses can be variable and unpredictable. In addition, handling of the package by the lead frames or the package body itself may also cause physical stress to MEMS device. Typically, the smaller the package, the more sensitive the MEMS die will be to these forces. Therefore, the size of the package becomes a limiting factor for MEMS applications.

What is needed is an inexpensive small scale package and method of assembly which isolates the MEMS device from the physical stresses in the package to allow improved operation of the MEMS device.

### BRIEF DESCRIPTION

A low cost micro-electronic package for MEMS applications includes a package substrate, a MEMS device and a buffer insert which is placed between the MEMS device and the package substrate. The buffer insert has a coefficient of thermal expansion (CTE) which is compatible with the material of the MEMS device and is sufficiently rigid to isolate the MEMS device from thermal, mechanical and other physical stresses applied to the package substrate. In an embodiment, the package is formed as an integrated device which includes both the MEMS device and a signal conditioning integrated circuit, potentially found in the same die. The substrate insert may be made of a material having a CTE value compatible with silicon (Si), such as Kovar, Invar, or an appropriate ceramic material or the like.

### BRIEF DESCRIPTION OF THE DRAWINGS

The accompanying drawings, which are incorporated into and constitute a part of this specification, illustrate one or more embodiments of the system and method and, together with the detailed description, serve to explain the principles and implementations of the system and method.

In the drawings:

FIG. 1 illustrates a perspective view of a molded package including a MEMS device and a buffer insert according to an embodiment.

FIG. 2 illustrates an exploded view of the molded package according to an embodiment.

FIG. 3A illustrates a partially exploded view of the molded package according to an embodiment.

FIG. 3B illustrates a broken view of the molded package in FIG. 3A according to an embodiment.

FIG. 4 illustrates a cross sectional view of the molded package including the MEMS device shown in FIG. 1 according to an embodiment.

FIG. 5 illustrates a broken view of the molded package in FIG. 1 according to an embodiment.

FIG. 6 illustrates a broken view of an existing molded package.

FIG. 7 illustrates a method of manufacturing in accordance with an embodiment.

### DETAILED DESCRIPTION

Embodiments are described herein in the context of a sensor package and method of fabrication thereof. Those of ordinary skill in the art will realize that the following detailed description is illustrative only and is not intended to be in any way limiting. Other embodiments will readily suggest themselves to such skilled persons having the benefit of this disclosure. Reference will now be made in detail to implementations of one or more embodiments as illustrated in the accompanying drawings. The same reference indicators will be used throughout the drawings and the following detailed description to refer to the same or like parts.

In the interest of clarity, not all of the routine features of the implementations and embodiments are shown and described. It will, of course, be appreciated that in the development of any such actual implementation, numerous implementation-specific decisions must be made in order to achieve the developer's specific goals, such as compliance with application- and bandwidth-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In general, the disclosure herein relates to low cost micro-electronic packages for MEMS applications and associated methods of manufacturing. In an embodiment, the micro-electronic package utilizes a buffer insert which is placed between a MEMS device and the package substrate. The buffer insert has a coefficient of thermal expansion (CTE) which is compatible with the material of the MEMS device and is sufficiently rigid to isolate the MEMS device from thermal, mechanical and other physical stresses applied to the packaging substrate. In an embodiment, the package is an integrated device which includes both the MEMS device and a signal conditioning integrated circuit. In an embodiment, the substrate insert is made of a material having a CTE value compatible with silicon (Si), including, but not limited to, Kovar, Invar, or an appropriate ceramic material, or the like, without digressing from the inventive concepts herein.

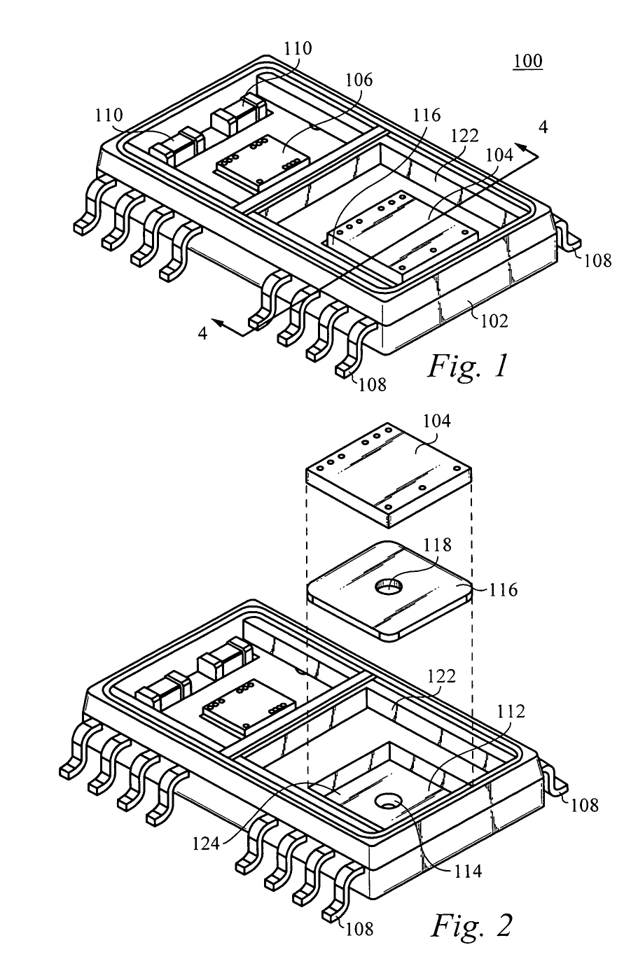

FIG. 1 illustrates a perspective view of a molded package according to an embodiment. As shown in an embodiment in FIG. 1, a sensor assembly 100 includes a micro-electronic package 102 which houses both a Micro Electronic-Mechanical System (MEMS) sensor 104 in one portion of the package 102 and a signal conditioning integrated circuit (SCIC) 106 and one or more capacitors 110 in another portion of the package 102. This is advantageous in that the sensor assembly 100 includes integrated components and is easily able to be implemented as a single packaged device in appropriate applications. In an embodiment, the package 100 only houses the MEMS sensor 104, whereby the SCIC 106 is incorporated in a separate package (not shown). The package 102 is formed of an injection molded polymer or ceramic material, although other materials and methods of manufacturing the package 102 are contemplated. The MEMS device 104 is a pressure sensor in an embodiment, although any other type of MEMS device may be housed in the package. Such MEMS devices include, but are not limited to, temperature sensors, Hall effect sensors, electromagnetic sensor and sensor arrays, humidity sensors, optical sensors, gyroscopes, accelerometers, piezoelectrics sensors or transducers, and displays.

As shown in FIG. 1, the package 102 of the sensor assembly 100 includes conductive leads 108 which allow the assembly 100 to be plugged into or otherwise coupled to the electronic circuitry of a circuit board or other appropriate dock, whereby power is supplied to the sensor assembly 100 and/or data is communicated via the conductive leads 108. In an embodiment, a power source is integrated into the sensor assembly 100. In an embodiment, sensed signals from the MEMS device 104 are wirelessly transmitted directly from the sensor assembly 100 to a receiver (not shown). Although the package 102 is shown in FIG. 1 to be an SOIC type, it is understood that any other type of mounting technology is contemplated including, but not limited to, surface mount technology, Ball Grid Arrays, solder bumps, flip chip, wire bonding and the like.

As shown in FIG. 1, the conductive leads 108 extend into the package 102 and are designed to connect to the MEMS device 104 and any other electronic components in the package 102 by appropriate methods, an example being wire bonding. The package 102 includes several outer walls which form a chamber 122 within which the MEMS device 104 is housed. The package 102 shown in FIG. 1 includes a bottom surface 124. In the embodiment shown in FIGS. 1 and 2, the bottom surface includes a recessed seat 112 which holds at least a portion of the MEMS device 104 along with the rigid buffer insert 116, as discussed below. In an embodiment, the seat 112 has a depth sufficient to allow the MEMS device 104 to be completely housed within the package 102. Although the seat 112 is shown in the embodiment in FIG. 2 to be square shaped, the seat 112 may have any shape which allows the MEMS device 104 to be seated in the seat 112. As shown in the embodiment in FIG. 2, the seat 112 includes an aperture 114 which extends from the bottom surface 124 to the outside surface of the package. It is to be understood that the package 102 alternatively does not have a recessed seat 112 but only a flat surface, whereby the buffer insert 116 is attached to the bottom surface of the chamber and the MEMS device 104 is attached to the opposite side of the buffer insert 116.

In an embodiment, the package 102 is formed of a thermo-set or thermo-plastic material, whereby the material of the package undergoes thermal expansion or contraction due to temperature changes. In addition, the conductive leads 108 as well as other components and circuits inside or outside of the package 102 may cause thermal expansions and contractions of materials in the package which cause stresses to the package 102. In addition, mechanical stresses may be applied to the package 102 from the environment surrounding the sensor assembly 100 (e.g. pressure within a tire). These physical stresses are transmitted through the materials in the package 102 and may be experienced by the MEMS device 104. Such stresses may cause cracks in the package 102 as well as the die surface of the MEMS device. In addition, the stresses may cause the MEMS device 104 to produce inaccurate and/or inconsistent measurements.

Accordingly, a rigid buffer insert 116 is incorporated in the package, whereby the buffer insert 116 isolates and protects the MEMS device 104 from physical stresses to the package 102. As shown in an embodiment in FIG. 2, a buffer insert 116 is mounted in the package 102, and in particular, in the recessed seat 112 of the package 102. In an embodiment, the buffer insert 116 is mounted to the bottom surface 124 of the chamber 122 of the package 102 if there is no recessed seat area 112. In an embodiment, the buffer insert 116 is suspended in the package 102 or attached to a surface other than the bottom surface 124, whereby the MEMS device 104 is attached to the one side of the buffer insert 116.

The buffer insert 116 is a rigid substrate which has a coefficient of thermal expansion (CTE) which substantially or closely matches the CTE of the die substrate of the MEMS device. The buffer insert 116, however, is also substantially rigid to withstand any stresses applied to it by physical and/or thermal changes to the packaging substrate or surrounding environment. In an embodiment, the buffer insert 116 is made of a material with a CTE of the range of approximately 1 to approximately 6 parts per million (ppm). Some examples of materials include, but are not limited to, Kovar, Invar, and ceramic material. However, it should be noted that the material of the buffer insert 116 may be any other material which has a thermal expansion characteristic which substantially matches that of the attaching or interface surface of the MEMS device, but is also sufficiently rigid to withstand the physical forces and stresses applied to it from the package and components of the package. It is to be noted that where CTEs are compatible, the respective CTEs of two materials should be close enough in value not to create significant thermally induced stress in the resulting structure during expected thermal cycling.

In an embodiment which incorporates the recessed seat 112, the length and/or width dimensions of the buffer insert 116 are slightly smaller than the respective dimensions of the seat 112 to provide some clearance therebetween. In an embodiment, the length and/or width dimensions of the buffer insert 116 are such that the buffer insert 116 snugly fits within the seat 112. As shown in the Figures, the buffer insert 116 includes an aperture 118 which is positioned to be aligned with the aperture 114 in the package substrate in an embodiment.

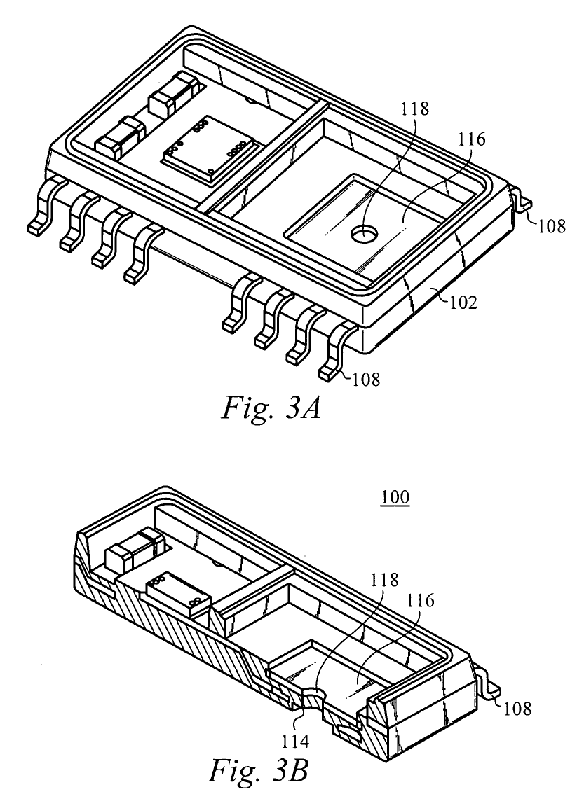

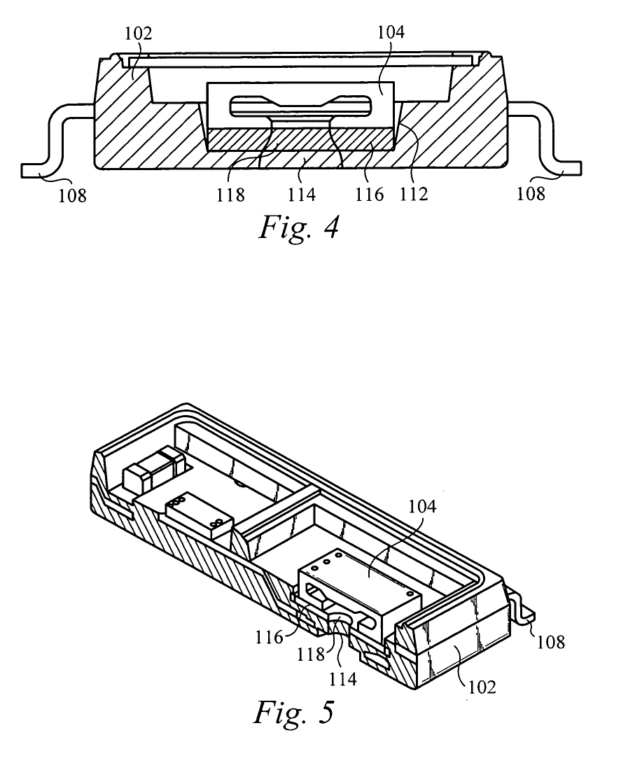

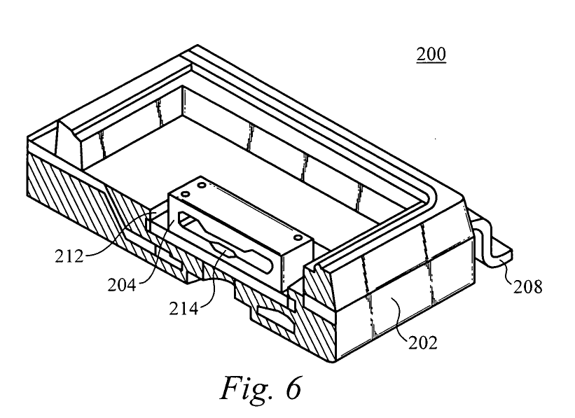

FIGS. 3A and 3B illustrate views of the sensor assembly 100 having the buffer insert according to an embodiment. A bottom surface of the buffer insert 116 is attached to the bottom surface of the package 102 by an adhesive, as shown in FIGS. 3A and 3B. As shown in FIGS. 4 and 5, the MEMS device 104 is mounted to a top surface of the buffer insert 116 by an adhesive. The rigidity of the material in the buffer insert 116 isolates the MEMS device 104 from any physical stresses in the leads 108 as well as the substrate of the package 102. In addition, the buffer insert 116 has a CTE value which allows it to thermally expand or contract along with the die surface of the MEMS device 104 to ensure stability of the MEMS device 104 and that no cracking occurs between the MEMS device 104 and the buffer insert 116. The buffer insert 116 thereby prevents the MEMS device 104 from experiencing any thermal, mechanical or any other physical stresses transmitted in the package 102.

The adhesive between the MEMS device 104 and the buffer insert 116 as well as between the buffer insert 116 and the bottom surface of the chamber is made of flourosilicone in an embodiment, although other types of adhesives are contemplated. The adhesive is chosen to provide additional isolation between the MEMS device 104 and the package 102.

The buffer insert 116 may be machined, stamped, or etched using appropriate technologies. In an embodiment, the buffer insert 116 is inserted into the package 102, as shown in FIGS. 2 and 3A-3B, and is mounted to the package by an appropriate adhesive. In an embodiment, the adhesive has a CTE which is compatible to that of the package 102 and the buffer insert 116. In another embodiment, the buffer insert 116 is initially formed by molding it in the seat 112 in the package 102. In the case that the buffer insert 116 is made of a ceramic, the buffer insert 116 may be initially sawn and then mounted in place in the seat 112 by an appropriate adhesive. Such methods of employing a buffer insert 116 allows the sensor assembly 100 to be produced relatively inexpensively while exhibiting improved performance in the presence of mechanical and thermal stresses.

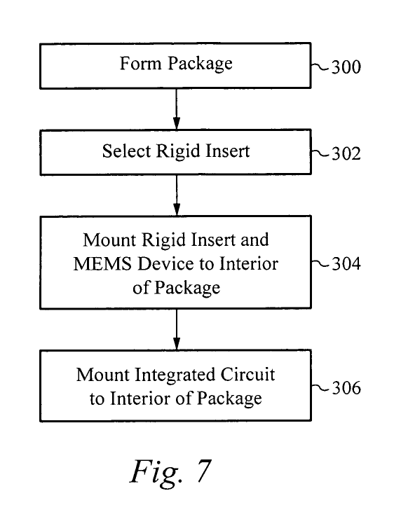

In an embodiment, as shown in FIG. 7, manufacture of the package assembly 100 is accomplished by first forming the package 102 by an appropriate method or technique (300). Following, a buffer insert 116 is selected (302), and the insert 116 as well as the MEMS device is mounted to the interior of the package. In an embodiment, the buffer insert 116 is mounted to the bottom surface 124 or recessed area in the chamber 122 of the package, whereby the MEMS device is then attached to the opposite side of the buffer insert 116 by an adhesive or attached by another suitable method. In an embodiment, the MEMS device 104 is attached to the buffer insert 116 first, whereby the integrated component is thereafter attached to the bottom surface of the package 102. In an embodiment, the package 102 is formed with the buffer insert 116 as one piece, whereby the MEMS device 104 is thereafter attached to the buffer insert 116. An aperture may be formed in the insert 116 and/or package 102, as shown in the Figures. The aperture(s) may be formed during the manufacturing process or before the components are coupled together to form the overall device assembly.

At any point in manufacturing the package assembly, conductive leads are formed in the package 102 by any appropriate method or technique. In an embodiment, an integrated circuit (e.g. ASIC, SOIC) is placed in the package and coupled to the conductive leads and/or other components in the package to form an integrated MEMS package with selected electronics therein (306). It should be noted that the above description of the manufacturing method is an example method and the process is not limited thereto. Other steps, techniques, configurations, components and processes are contemplated without departing from the subject matter contemplated herein.

While particular embodiments of the present invention have been shown and described, it will be obvious to those skilled in the art that, based upon the teachings herein, changes and modifications may be made without departing from the one or more embodiments described herein and its broader aspects. Therefore, the appended claims are intended to encompass within their scope all such changes and modifications as are within the true spirit and scope of the one or more embodiment.

What is claimed is:

1. A Micro Electronic-Mechanical System (MEMS) package assembly comprising:
a package having a plurality of walls configured to form a chamber within the package, the chamber; and
an insert coupled to a surface within the chamber and adapted to attach a MEMS device thereon, the insert having a thermal expansion characteristic compatible with at least a portion of the MEMS device, wherein the insert is configured to isolate the MEMS device from a stress force applied in the package.

2. The assembly of claim 1 wherein the package includes a bottom surface within the chamber, wherein at least a portion of the insert is coupled to the bottom surface.

3. The assembly of claim 1 wherein the package includes a bottom surface within the chamber having a recessed area, wherein the insert is coupled to the bottom surface and placed at least partially into the recessed area.

4. The assembly of claim 1 further comprising a MEMS device attached to the insert, wherein a coefficient of thermal expansion (CTE) of the insert is substantially similar to a CTE of the MEMS device.

5. The assembly of claim 1 wherein the package further comprises:
a plurality of conductive leads; and
an integrated circuit positioned within the chamber and coupled to at least one of the conductive leads.

6. The assembly of claim 1 wherein the chamber is partitioned into a first chamber and a second chamber, wherein a MEMS device is positioned in the first chamber and an integrated circuit is positioned in the second chamber.

7. The assembly of claim 1 wherein the insert is made of at least one of Kovar, Invar and a ceramic material.

8. The assembly of claim 1 wherein the insert includes an aperture therethrough.

9. A Micro Electronic-Mechanical System (MEMS) device assembly comprising:
a package having a plurality of walls configured to form a chamber within the package, the chamber having a seating portion;
a MEMS device housed within the package and having an interface surface; and
a rigid insert made of a material having a coefficient of thermal expansion value (CTE) compatible with a CTE value of the interface surface of the MEMS device, wherein a first surface of the insert is attached to the MEMS device and a second surface of the insert is mounted to the seating portion.

10. The assembly of claim 9 wherein the seating portion includes a recessed area, wherein the insert is placed at least partially into the recessed area.

11. The assembly of claim 9 wherein the package further comprises:
a plurality of conductive leads; and
an integrated circuit positioned within the chamber and coupled to at least one of the conductive leads.

12. The assembly of claim 9 wherein the chamber is partitioned into a first chamber and a second chamber, wherein the MEMS device is positioned in the first chamber and an integrated circuit is positioned in the second chamber.

13. The assembly of claim 9 wherein the insert is made of at least one of Kovar, Invar and ceramic material.

14. The assembly of claim 9 wherein the insert includes an aperture therethrough.

15. A method for manufacturing a package assembly for a Micro Electronic-Mechanical System (MEMS) device, the method comprising:
forming a package having a plurality of walls configured to form a chamber within the package, the chamber having a bottom surface;
selecting a MEMS device having a die surface; and
coupling the MEMS device to a rigid insert, wherein the insert is positioned between the bottom surface of the package and the die surface of the MEMS device, the insert having a thermal expansion characteristic compatible with the die surface and configured to isolate the MEMS device from a stress force applied to the package.

16. The method of claim 15 further comprising forming a recessed area into the bottom surface, wherein the insert is able to be placed at least partially into the recessed area.

17. The method of claim 15 further comprising:
forming a plurality of conductive leads in the package; and
coupling an integrated circuit to at least one of the conductive leads.

18. The method of claim 15 wherein the insert is made of at least one of Kovar, Invar and ceramic material.

19. The method of claim 15 wherein the MEMS device is coupled to insert after the insert is coupled to the bottom surface of the package.

20. The method of claim 15 wherein the MEMS device is coupled to insert before the insert is coupled to the bottom surface of the package.
